(19) United States
(12) Patent Application Publication
(10) Pub. No.: US 2024/0332116 A1
(43) Pub. Date: Oct. 3, 2024

(54) SEMICONDUCTOR DEVICE THERMAL INTERFACE AND METHOD

(71) Applicant: Intel Corporation, Santa Clara, CA (US)

(72) Inventor: Chun Keang Ooi, Lunes (MY)

(21) Appl. No.: 18/128,126

(22) Filed: Mar. 29, 2023

(51) Int. Cl. H01L 23/367; H01L 23/00

(52) U.S. Cl. CPC H01L 23/3675; H01L 24/29; H01L 24/32; H01L 24/83; H01L 21/50; H01L 2224/29105; H01L 2224/32257; H01L 2224/83099; H01L 2224/83104; H01L 2924/20102

(57) ABSTRACT

An electronic device and associated methods are disclosed. In one example, the electronic device includes a thermal interface material between a heat spreader and a semiconductor die. In selected examples, the thermal interface material includes a liquid metal, and the heat spreader includes a top opening that is used to introduce the thermal interface material to a space between the die and the heat spreader.

### TECHNICAL FIELD

Embodiments described herein generally relate to semiconductor devices and packaging. Specific examples include thermal interface materials between a die and an integrated heat spreader and associated methods.

### BACKGROUND

Thermal interface solutions have been employed between a die and integrated heat spreaders. A good thermal connection provides improved thermal conduction between the die and the integrated heat spreader, which in turn provides improved removal of heat from the die during operation. Imperfections in the interface between the die and the heat spreader can reduce effective heat transfer. It is desired to have device configurations and methods that address these concerns, and other technical challenges.

### BRIEF DESCRIPTION OF THE DRAWINGS

FIG. 1A shows an electronic device in a stage of manufacture in accordance with some example embodiments.

FIG. 1B shows the electronic device from FIG. 1A, in another stage of manufacture in accordance with some example embodiments.

FIG. 1C shows the electronic device from FIG. 1A in accordance with some example embodiments.

FIG. 1D shows the electronic device from FIG. 1A in accordance with some example embodiments.

FIG. 1E shows the electronic device from FIG. 1A in accordance with some example embodiments.

FIG. 2 shows a portion of an electronic device in a stage of manufacture in accordance with some example embodiments.

FIG. 3A shows a portion of an electronic device in a stage of manufacture in accordance with some example embodiments.

FIG. 3B shows the electronic device from FIG. 3A, in another stage of manufacture in accordance with some example embodiments.

FIG. 4A shows an electronic device in a stage of manufacture in accordance with some example embodiments.

FIG. 4B shows the electronic device from FIG. 4A, in another stage of manufacture in accordance with some example embodiments.

FIG. 4C shows the electronic device from FIG. 4A in accordance with some example embodiments.

FIG. 5 shows a flow diagram of a method of manufacture of an electronic device in accordance with some example embodiments.

FIG. 6 shows a system that may incorporate a thermal interface material and heat spreader and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

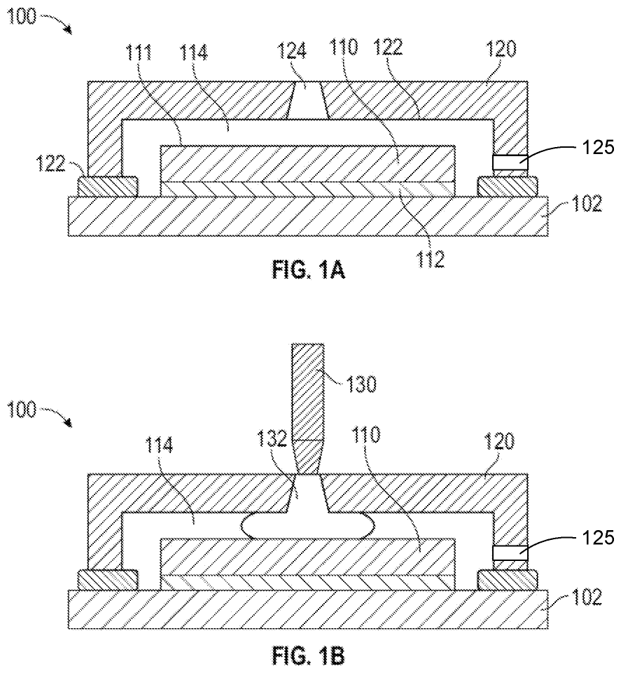

FIG. 1A shows an electronic device 100. The electronic device 100 includes a semiconductor die 110 coupled to a substrate 102. Examples of die 110 include, but are not limited to, processor dies, memory dies, graphics dies, etc. The electronic device 100 further includes a heat spreader 120 covering the semiconductor die 110. In one example, the heat spreader 120 includes an integrated heat spreader, which may be formed from a single stamped sheet of conductive material, such as metal. Other examples of heat spreaders 120 are also within the scope of the invention. In the example of FIG. 1A, an adhesive 122 is included to secure the heat spreader 120 to the substrate 102. Other examples may not include an adhesive 122.

A top opening 124 is included in the heat spreader 120 above a portion of the die 110. In one example, the top opening 124 provides injection of a flowable thermal interface material into a space 114 between a top surface 111 of the semiconductor die 110 and an internal surface 122 of the heat spreader 120.

FIG. 1B shows a nozzle 130 that is injecting or otherwise providing an amount of thermal interface material 132 into the space 114. FIG. 1C shows a point in manufacture subsequent to FIG. 1B, where the amount of thermal interface material 132 has spread across the top surface 111 of the die 110 and across the interior surface 122 of the heat spreader 120. In the example shown, the thermal interface material 132 bridges across the top opening 124. In one example, the top opening 124 also remains filled with the thermal interface material 132, as shown in FIG. 1C, although the invention is not so limited. In one example, a relief opening 125 is further included to allow air to escape as the thermal interface material 132 is injected into the space 114. Although FIG. 1A-1E show the relief opening 125 located along a side of the heat spreader 120, the invention is not so limited. Other locations along the heat spreader 120 or anywhere in communication with space 114 are within the scope of the invention.

FIG. 1D shows additional physical device characteristics of a resulting thermal interface material 132 after manufacture using methods and materials described in the present disclosure. In FIG. 1D, the top opening 124 is partially filled with a portion 134 of the thermal interface material 132, but not completely filled. Although a convex top surface of portion 134 is shown, other shapes of portion 134, such as concave or flat are within the scope of the invention and may result from different material combinations and corresponding surface energies of materials. In FIG. 1D, a side portion 136 of the thermal interface material 132 is shown covering at least a portion of a side 113 of the die 110. All or a portion of sides 11 of the die 110 may be covered depending on surface energies, and how much thermal interface material 132 is injected.

FIG. 1E shows another example of physical device characteristics of a resulting thermal interface material 132 after manufacture using methods and materials described in the present disclosure. In FIG. 1E, a discontinuous portion 138 of the thermal interface material 132 is shown, separated from the side portion 136 of the thermal interface material 132 by a gap 139. In one example, such a configuration may result from an amount of the thermal interface material 132 dripping or otherwise separating from the side portion 136 of the thermal interface material 132.

In one example, the top opening 124 is located in a center of a top surface of the heat spreader. This location allows the thermal interface material 132 to spread outwards in a consistent pattern and cover all or a majority of the top surface 111 of the die 110. Other locations are possible, including at a center along one edge of the top surface 111 of the die 110, at a corner of the top surface 111 of the die 110, or other locations over the top surface 111 of the die 110.

In one example, the thermal interface material 132 includes a thermal conductor that is liquid at room temperature. In one example, the thermal interface material 132 includes a liquid metal. Examples of liquid metal, include, but are not limited to, gallium based materials.

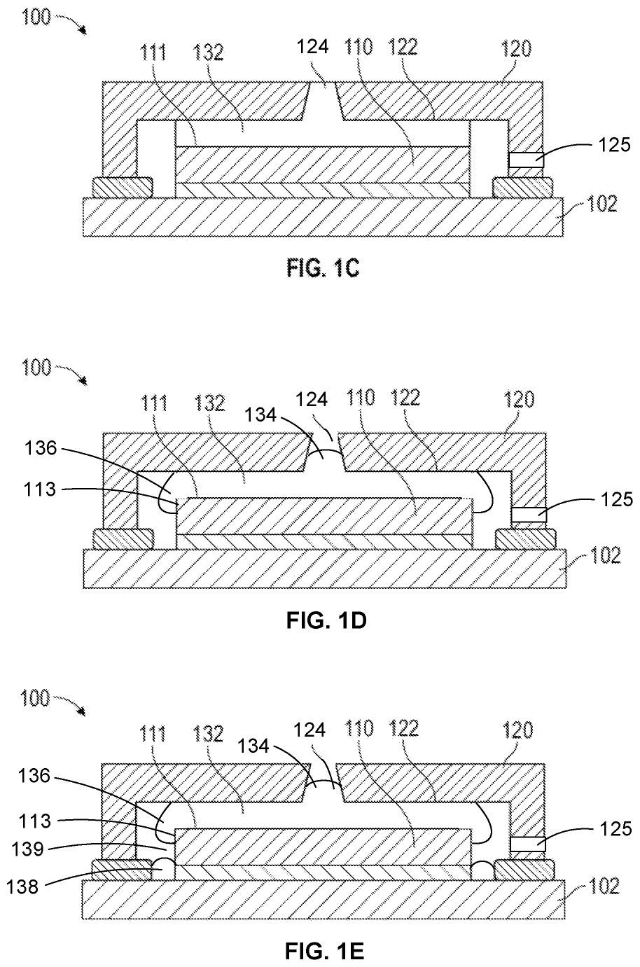

FIG. 2 shows a close up view of a top opening 224 similar to the top opening 124 from FIG. 1A-1C. The top opening 224 is located in a portion of a heat spreader 220. A nozzle 230 is shown dispensing an amount of thermal interface material 232. Similar to the examples of FIGS. 1A-1C, in one example, the thermal interface material 232 includes a thermal conductor that is liquid at room temperature. In the example of FIG. 2, the top opening 224 includes a chamfer 225 on a sidewall of the top opening 224. The chamfer 225 enhances flow of the thermal interface material 232 providing improved distribution within the space between a top surface of the die and across an interior surface of the heat spreader 220.

In the example of FIG. 2, the chamfer 225 is linear, and forms a straight slant from an exterior surface 221 of the heat spreader 220 to an interior surface 222 of the heat spreader 220. Other examples of a chamfer 225 include an arced transition, or a stepped transition from the exterior surface 221 of the heat spreader 220 to an interior surface 222 of the heat spreader 220. A wider opening at the interior surface 222 of the heat spreader 220 than at the exterior surface 221 of the heat spreader 220 provides an amount of improved spreading effect.

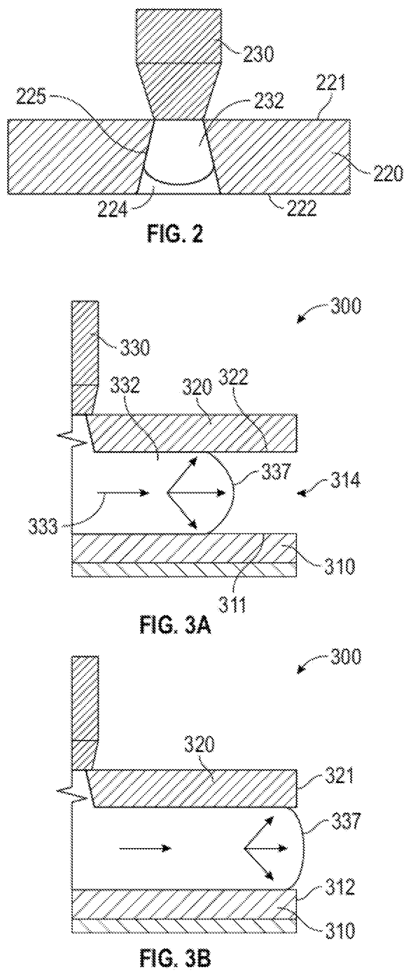

FIG. 3A shows selected portions of an electronic device 300 in manufacture. Similar to earlier examples, a nozzle 330 is shown dispensing an amount of thermal interface material 332. Similar to other examples, the thermal interface material 332 includes a thermal conductor that is liquid at room temperature. FIG. 3A shows a top opening 324 similar to the top opening 224 from FIG. 2. The top opening 224 is located in a portion of a heat spreader 320. A space 314 is shown between a top surface 311 of the die and across an interior surface 322 of the heat spreader 320.

Flow of the thermal interface material 332 is indicated by arrows 333. In FIG. 3A, an advancing edge 337 of the thermal interface material 332 is shown with a convex shape. A shape of the advancing edge 337 of the thermal interface material 332 is determined by a number of factors, including pressure from the nozzle, and surface energy differences between the thermal interface material 332 and the directly adjacent surface materials of the top surface 311 of the die and the interior surface 322 of the heat spreader 320. In selected configurations, the edge 337 may be concave.

FIG. 3B shows the electronic device 300 from FIG. 3A after the thermal interface material 332 reaches an edge 312 of the die and/or an edge 321 of the heat spreader 320. In FIG. 3B, the edge 337 of the thermal interface material 332 is shown as convex. Similar to the discussion of FIG. 3A, factors such as pressure in forming, and surface energy differences in material interfaces determine the shape of the edge 337 of the thermal interface material 332.

When a thermal interface material is placed on a die then a heat spreader is placed on top of the thermal interface material, voids in the thermal interface material may develop. In one example, as a result of filling thermal interface material through a top opening in a heat spreader, voids are not present within the thermal interface material. If voids are present in a thermal interface material an effective amount of heat transfer is reduced between the die 310 and the heat spreader 320. It is desirable to have a high heat transfer between the die 310 and the heat spreader 320, therefore, voids are undesirable. By using a liquid thermal interface material distributed through a top opening in a heat spreader, voids are not present, and heat transfer is more effective.

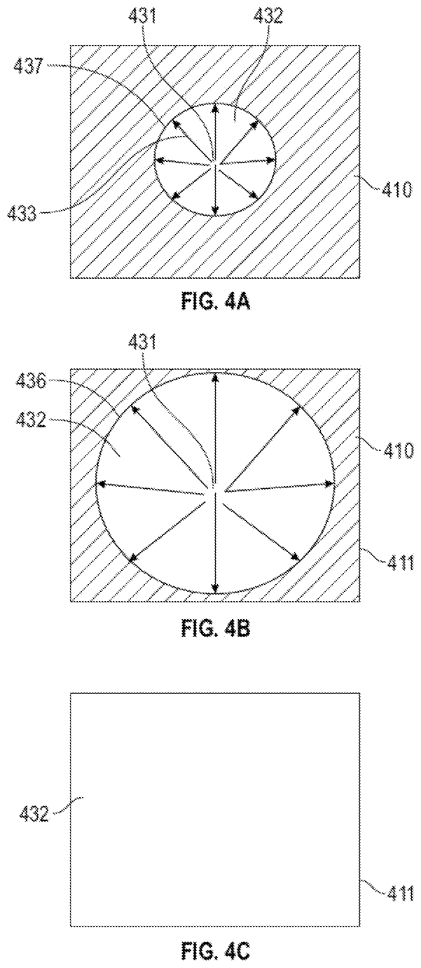

FIGS. 4A-4C show a top view of spreading of a thermal interface material 432 over a top surface of a die. 410. A top opening location 431 is indicated over the die 410. Similar to examples discussed above, one location for the top opening is in a center of the die 410, and/or a center of a heat spreader (not shown). A flow of the thermal interface material 432 is indicated by arrows 433.

In FIG. 4A, an edge 437 of the thermal interface material 432 is expanding outwards from the top opening location 431. In FIG. 4B, the edge 437 of the thermal interface material 432 is approaching an edge 411 of the die 410. In FIG. 4C, the edge 437 of the thermal interface material 432 fills out to contact all edges 411 of the die 410. In one example, surface tension (which is a function of surface energies of the materials) guides the liquid thermal interface material 432 to form a rectangular conforming layer over the die 410. In other examples, the thermal interface material 432 may substantially cover the die 410, but leave some exposed portions near corners of the die.

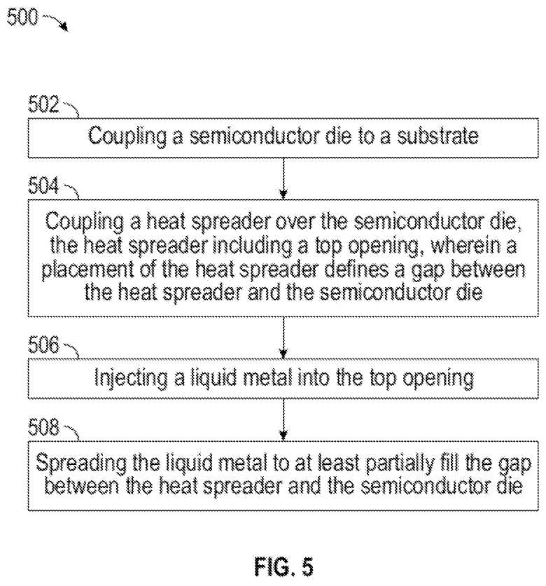

FIG. 5 shows a flow diagram of one example method of manufacture of an electronic device as described. In operation 502, a semiconductor die is coupled to a substrate. In operation 504, a heat spreader is coupled over the semiconductor die, the heat spreader including a top opening. A placement of the heat spreader defines a gap between the heat spreader and the semiconductor die. In operation 506, a liquid metal is injected into the top opening, and in operation 508, the liquid metal is spread to at least partially fill the gap between the heat spreader and the semiconductor die.

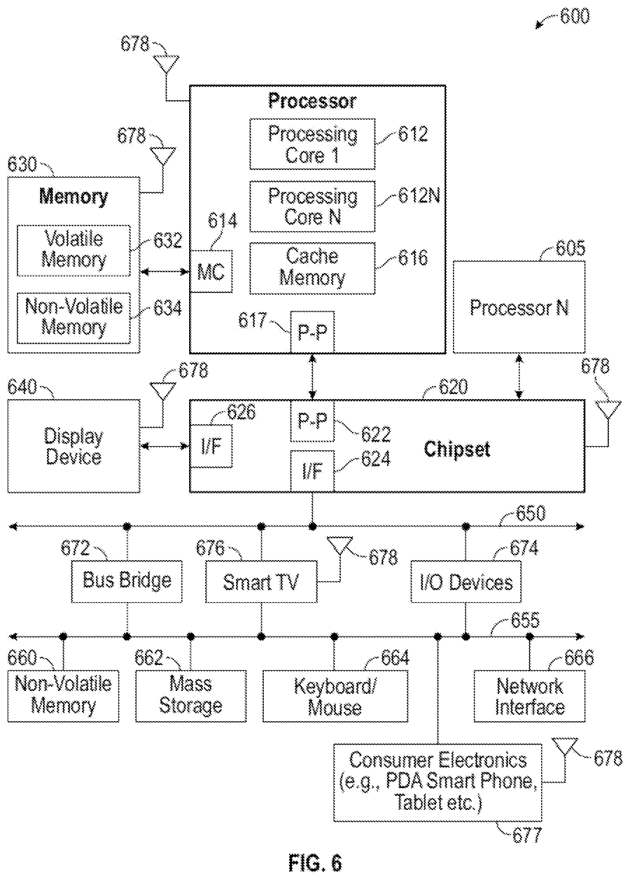

FIG. 6 illustrates a system level diagram, depicting an example of an electronic device (e.g., system) that may include a thermal interface material and heat spreader configuration and/or methods described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

To better illustrate the method and apparatuses disclosed herein, a non-limiting list of embodiments is provided here:
Example 1 includes an electronic device. The electronic device includes a semiconductor die coupled to a substrate, and a heat spreader covering the semiconductor die. The heat spreader includes a top opening. The electronic device also includes a thermal interface material in thermal communication between a top surface of the semiconductor die and an internal surface of the heat spreader, wherein the thermal interface material bridges across the top opening.
Example 2 includes the electronic device of example 1, wherein the top opening is located in a center of a top surface of the heat spreader.
Example 3 includes the electronic device of any one of examples 1-2, wherein the top opening includes a chamfer.
Example 4 includes the electronic device of any one of examples 1-3, wherein the chamfer is linear.
Example 5 includes the electronic device of any one of examples 1-4, wherein the top opening is filled with the thermal interface material.
Example 6 includes the electronic device of any one of examples 1-5, wherein the thermal interface material includes a liquid metal.
Example 7 includes the electronic device of any one of examples 1-6, wherein the liquid metal includes gallium.
Example 8 includes the electronic device of any one of examples 1-7, wherein edges of the thermal interface material are convex.
Example 9 includes an electronic device. The electronic device includes a semiconductor die coupled to a substrate. The electronic device also includes a heat spreader covering the semiconductor die, the heat spreader including a top opening. The electronic device also includes a liquid metal in thermal communication between a top surface of the semiconductor die and an internal surface of the heat spreader, wherein the liquid metal bridges across the top opening, and an antenna coupled to the semiconductor die.
Example 10 includes the electronic device of example 9, wherein the liquid metal includes gallium.
Example 11 includes the electronic device of any one of examples 9-10, wherein the top opening includes a chamfer.
Example 12 includes the electronic device of any one of examples 9-11, wherein the chamfer is linear.
Example 13 includes the electronic device of any one of examples 9-12, wherein the top opening is filled with the thermal interface material.
Example 14 includes the electronic device of any one of examples 9-13, further including a touchscreen.
Example 15 includes the electronic device of any one of examples 9-14, wherein the semiconductor die includes a processor die.
Example 16 includes a method of forming an electronic device. The method includes coupling a semiconductor die to a substrate, coupling a heat spreader over the semiconductor die, the heat spreader including a top opening, wherein a placement of the heat spreader defines a gap between the heat spreader and the semiconductor die, injecting a liquid metal into the top opening, and spreading the liquid metal to at least partially fill the gap between the heat spreader and the semiconductor die.
Example 17 includes the method of example 16, wherein injecting a liquid metal includes injecting at room temperature.
Example 18 includes the method of any one of examples 16-17, wherein spreading the liquid metal includes spreading from a center of the semiconductor die outwards towards edges of the semiconductor die.
Example 19 includes the method of any one of examples 16-18, wherein spreading the liquid metal includes spreading a gallium based liquid metal.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device, comprising:
a semiconductor die coupled to a substrate;
a heat spreader covering the semiconductor die, the heat spreader including a top opening; and
a thermal interface material in thermal communication between a top surface of the semiconductor die and an internal surface of the heat spreader, wherein the thermal interface material bridges across the top opening.

2. The electronic device of claim 1, wherein the top opening is located in a center of a top surface of the heat spreader.

3. The electronic device of claim 1, wherein the top opening includes a chamfer.

4. The electronic device of claim 3, wherein the chamfer is linear.

5. The electronic device of claim 1, wherein the top opening is filled with the thermal interface material.

6. The electronic device of claim 1, wherein the thermal interface material includes a liquid metal.

7. The electronic device of claim 6, wherein the liquid metal includes gallium.

8. The electronic device of claim 1, wherein edges of the thermal interface material are convex.

9. An electronic device, comprising:
a semiconductor die coupled to a substrate;
a heat spreader covering the semiconductor die, the heat spreader including a top opening;
a liquid metal in thermal communication between a top surface of the semiconductor die and an internal surface of the heat spreader, wherein the liquid metal bridges across the top opening; and
an antenna coupled to the semiconductor die.

10. The electronic device of claim 9, wherein the liquid metal includes gallium.

11. The electronic device of claim 9, wherein the top opening includes a chamfer.

12. The electronic device of claim 11, wherein the chamfer is linear.

13. The electronic device of claim 12, wherein the top opening is filled with the thermal interface material.

14. The electronic device of claim 8, further including a touchscreen.

15. The electronic device of claim 8, wherein the semiconductor die includes a processor die.

16. A method of forming an electronic device, comprising:
coupling a semiconductor die to a substrate;
coupling a heat spreader over the semiconductor die, the heat spreader including a top opening, wherein a placement of the heat spreader defines a gap between the heat spreader and the semiconductor die;
injecting a liquid metal into the top opening; and
spreading the liquid metal to at least partially fill the gap between the heat spreader and the semiconductor die.

17. The method of claim 16, wherein injecting a liquid metal includes injecting at room temperature.

18. The method of claim 16, wherein spreading the liquid metal includes spreading from a center of the semiconductor die outwards towards edges of the semiconductor die.

19. The method of claim 16, wherein spreading the liquid metal includes spreading a gallium based liquid metal.
